(19) United States
(12) Patent Application Publication
(10) Pub. No.: US 2016/0175804 A1
(43) Pub. Date: Jun. 23, 2016

(54) Laser-Induced Borane Production for Ion Implantation

(71) Applicant: Axcelis Technologies, Inc., Beverly, MA (US)

(72) Inventors: William Davis Lee, Newburyport, MA (US); William DiVergilio, Cambridge, MA (US); Daniel R. Tieger, Manchester, MA (US)

(21) Appl. No.: 14/576,549

(22) Filed: Dec. 19, 2014

(51) Int. Cl. B01J 19/12; H01J 37/08; C01B 35/02; H01J 37/317

(52) U.S. Cl. CPC B01J 19/121; H01J 37/3171; H01J 37/08; C01B 35/026; H01J 2237/31701; H01J 2237/08; B01J 2219/0875; B01J 2219/0871; B01J 2219/0869; B01J 2219/12

(57) ABSTRACT

Systems and methods for the production of laser induced high mass molecular borane is disclosed for an ion implantation system. The system comprises a laser, a diborane gas source, a heated interaction chamber for generating a high mass molecular borane, a transport system for transferring the high mass molecular borane, and an ion source chamber for generating an ion beam in an ion beam path for implantation of a workpiece. The transport system comprises at least a first and a second flow control component at least a first heated chamber, wherein the first heated chamber is disposed between the first and second flow control components, and wherein the first heated chamber is configured to condense the high mass molecular borane. The laser comprises a CO₂ laser configured to irradiate the diborane source gas at a wavelength of about 10.6 μm at a R-16 (973 cm⁻¹) line of excitation.

### FIELD

The present disclosure relates generally to ion implantation systems, and more particularly to a system and method for the production of high mass molecular species for use in ion implantation.

### BACKGROUND

Ion implantation is a physical process that is employed in semiconductor apparatus fabrication to selectively implant dopant into a semiconductor workpiece and/or wafer material. Thus, the act of implanting does not rely on a chemical interaction between a dopant and the semiconductor material. For ion implantation, dopant atoms/molecules are ionized and isolated, sometimes accelerated or decelerated, formed into a beam, and swept across a workpiece or wafer. The dopant ions physically bombard the workpiece, enter the surface and typically come to rest below the workpiece surface in the crystalline lattice structure thereof.

High mass molecular species are generally useful as implant dopants, specifically when low energy implants are required. Molecular implants allow for much lower effective energies due to the multitude of atoms in the molecule. The ratio of the mass of the atom to the mass of the molecule will give the appropriate energy scaling. Due to the low energies required for boron implants, boron is a likely candidate for molecular implants.

In a traditional boron doping process, boron atoms are directed toward a substrate with sufficient energy to penetrate the crystal lattice to a desired depth, and the substrate is then annealed to distribute the boron and activate it (attach it to the crystal network). As device dimensions grow smaller, control of implantation depth becomes more critical. Next generation devices are expected to have junctions no more than about 50 atomic layers deep.

Implantation problems arise as junction depth diminishes. Because the ions must travel more slowly to avoid implanting too deeply, the repulsive charge among like-charged ions forces them to diverge from their intended path. To compensate for this effect, fast-moving ions are magnetically decelerated near the surface of the substrate. Beam deceleration, however, results in energy contamination, arising from exchange of charge between fast-moving ions and fugitive neutral particles during or prior to deceleration. The fast-moving neutralized particles are unaffected by the beam decelerator and implant deeply into the substrate.

Small ions also channel through the crystal lattice. Because the crystal lattice has open spaces large enough for many ions to pass unimpeded, more ions will travel down these channels, resulting in highly variable implant depth. To reduce the tendency to channel, many manufacturers have resorted to pre-amorphizing the substrate surface to remove any opportunity for channeling. Pre-amorphization may also improve implant dose by opening more space within the solid matrix for ions to penetrate. Pre-amorphized substrates require more annealing, however, to activate dopants because the crystal structure is completely disrupted to a considerable depth and must be repaired. This leads to unwanted dopant diffusion and residual EOR damage. However, high mass boranes are quite expensive, and in some cases, have other undesirable properties.

### SUMMARY

The following presents a simplified summary in order to provide a basic understanding of one or more aspects of the disclosure. This summary is not an extensive overview of the disclosure, and is neither intended to identify key or critical elements of the disclosure, nor to delineate the scope thereof. Rather, the primary purpose of the summary is to present some concepts of the disclosure in a simplified form as a prelude to the more detailed description that is presented later.

The present disclosure is directed towards an assembly for the production of high mass molecular diborane for ion implantation comprising a laser, a diborane source gas, a heated interaction chamber for generating a high mass molecular borane, and a transport system for transferring the high mass molecular borane. The assembly further comprise an ion source chamber for generating an ion beam in an ion beam path for implantation of a workpiece, a beamline system and a process chamber.

In another embodiment, there is provided an interaction and transport system for the production and transfer of high mass molecular borane in an ion implantation system which includes a temperature controlled interaction chamber, at least a first and a second flow control component, and at least a first heated chamber, the first chamber disposed between the first and second flow control components, the first chamber operable to condense the high mass molecular borane.

In another embodiment, methods provide for the production of high mass molecular boranes in an ion implantation in which a CO₂ laser is provided to irradiate diborane at a predetermined power level in a temperature and pressure controlled interaction chamber to produce the high mass molecular boranes. The high molecular mass diborane is then transferred to an ion source chamber of the ion implantation system for implanting into a workpiece.

To the accomplishment of the foregoing and related ends, the following description and annexed drawings set forth in detail certain illustrative aspects and implementations of the disclosure. These are indicative of but a few of the various ways in which the principles of the disclosure may be employed. Other aspects, advantages and novel features of the disclosure will become apparent from the following detailed description of the disclosure when considered in conjunction with the drawings.

### BRIEF DESCRIPTION OF THE DRAWINGS

FIG. 1 is a schematic block diagram illustrating components of an ion implantation system in accordance with one or more aspects of the disclosure.

FIG. 2 is a flow diagram illustrating a method in accordance with the disclosure.

FIGS. 3A-3C are graphs illustrating valve operation as a function of time for material transfer in accordance with one or more aspects of the disclosure.

FIGS. 4A-4C are graphs illustrating chamber temperature as a function of time for material transfer in accordance with an aspect of the disclosure.

### DETAILED DESCRIPTION

The disclosure will now be described with reference to the drawings wherein like reference numerals are used to refer to like elements throughout. The illustrations and following descriptions are exemplary in nature, and not limiting. Thus, it will be appreciated that variants of the illustrated systems and methods and other such implementations apart from those illustrated herein are deemed as falling within the scope of the present disclosure and the appended claims.

The disclosure facilitates ion implantation with high mass boranes by producing higher mass boranes from low mass boranes, specifically, di-boranes, utilizing laser induced chemistry, in combination with an interaction chamber.

The boron macromolecules useful in the disclosure may comprise a mixture of stable boron macromolecules, including but not limited to the boron hydrides. For example, boron containing molecules in the form of BₓH_{y} may comprise molecules where x may range from 10 and 20, and y may be in the range of x+/−4, or range from 6 to 24. Some exemplary boron hydride molecules include one or more of icosaborane (B₂₀H₂₄), octadecaborane (B₁₈H₂₂), decaborane (B₁₀H₁₄), hexaborane (B₆ H₁₀), octaborane (B₈H₁₂), and hexadecaborane (B₁₆H₂₀). In one embodiment, the boron molecule used for implantation will be icosaborane. Because icosaborane ions have a high mass-to-charge ratio, the tendency for the ions to diverge is sharply reduced, allowing low energy implant with none of the challenges described above.

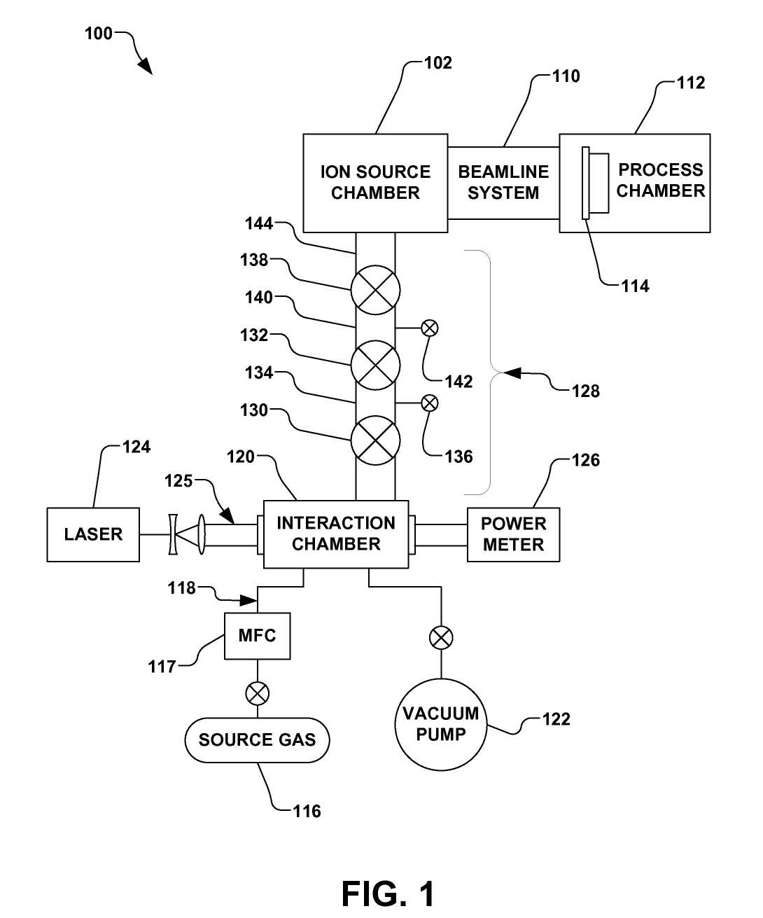

Referring then, to FIG. 1, an ion implantation system 100 suitable for implementing one or more aspects of the present disclosure is depicted in block diagram form. The system 100 is presented for illustrative purposes and it is appreciated that aspects of the disclosure are not limited to the described ion implantation system and that other suitable ion implantation systems of varied configurations can also be employed. The ion implantation system is generally used to implant ions by colliding an ion beam with a semiconductor workpiece, which is used for integrated circuits and the like.

The system 100 includes an ion source chamber 102 for producing an ion beam along a beam path. A beamline system 110 is provided downstream of the ion source chamber 102 to receive a beam therefrom. The beamline system 110 may include (not shown) a mass analyzer, an acceleration structure, which may include, for example, one or more gaps, and an angular energy filter. The beamline system 110 is situated along the path to receive the beam. The mass analyzer includes a field generating component, such as a magnet, and operates to provide a field across the beam path so as to deflect ions from the ion beam at varying trajectories according to mass (e.g., charge to mass ratio). Ions traveling through the magnetic field experience a force which directs individual ions of a desired mass along the beam path and which deflects ions of undesired mass away from the beam path.

A process chamber 112 is provided in the system 100, which receives a mass analyzed ion beam from the beamline system 110 and supports one or more workpieces 114 such as semiconductor wafers along the path for implantation using the final mass analyzed ion beam. The process chamber 112 then receives the ion beam which is directed toward a workpiece 114. It is appreciated that different types of process chambers 112 may be employed in the system 100. For example, a “batch” type process chamber 112 can simultaneously support multiple workpieces 114 on a rotating support structure, wherein the workpieces 114 are rotated through the path of the ion beam until all the workpieces 114 are completely implanted. A “serial” type plasma chamber 114, on the other hand, supports a single workpiece 114 along the beam path for implantation, wherein multiple workpieces 114 are implanted one at a time in serial fashion, with each workpiece 114 being completely implanted before implantation of the next workpiece 114 begins. The process chamber 112 may also include a scanning apparatus for moving the beam with respect to the workpiece, or the workpiece with respect to the beam.

Boron-containing process gases including gaseous compounds such as diborane, for example, are supplied from the gas source 116, and are introduced through a mass flow controller 117 and a conduit 118 into interaction chamber 120, wherein interactions will lead to formation of high molecular mass boranes. For example, high molecular mass boranes may include octadecaborane (B₁₈) and/or icosaborane (B₂₀). Interaction chamber 120 may be temperature and pressure controlled. In one embodiment the temperature of interaction chamber 120 will be sufficient to condense heavier borane molecules, while lower molecular weight borane molecules will remain in reflux. In one embodiment, the temperature of the interaction chamber 120 comprises from about 40° C. to about 80° C. In one embodiment, the pressure of the interaction chamber will comprise from about 50 torr to about 400 torr.

A vacuum pump 122, for example, is operatively coupled to interaction chamber 120 to control pressure therein. A laser 124 and associated optics, for example, is configured to produce laser light 125 in order to irradiate the interaction chamber 120 containing the diborane source gas. For example, the laser 124 comprises a CO₂ laser, wherein the laser light 125 is emitted at a wavelength of 10.6 μm, which corresponds to a so-called “wagging mode” for exciting the diborane molecules. The “wagging mode” of the laser 124 thus breaks the chemical bonds of the diborane. Lasers 124 of other varieties may be alternatively used to produce similar wavelengths or alternative wavelengths to break the chemical bonds of the diborane, either in a wagging mode, or other excitation modes, and all such lasers, wavelengths, and excitation modes are contemplated in the present disclosure. The laser light 125, for example, enters the interaction chamber 120 at a predetermined power level, such as at an R-16 (973 cm⁻¹) line of excitation. A power meter 126, for example, monitors the power of the laser 124 at the exit of interaction chamber 120. The diborane gas within the interaction chamber 120, for example, may be irradiated by pulsing the laser 124 for predetermined time period, or the laser may be operated continuously.

A transport system 128 is further operably coupled to interaction chamber 120. In one embodiment, the transport system 128, for example, comprises at least two temperature controlled flow components 130, 132, and at least a first heated chamber 134 for transport of the high mass boranes from interaction chamber 120 to ion source chamber 102. Associated with first heated chamber 134 is a first pressure control valve 136. The first heated chamber 134, for example, may be disposed between first and second flow control components 128, 130. The first heated chamber 134, for example, is operable to condense the high mass molecular borane. Thus, the first heated chamber 134, for example, may be sufficiently heated to condense the high mass borane, while lighter mass boranes are kept in reflux. Associated with first heated chamber 134 is a first pressure valve 136. The first pressure control valve 136, in one example, maintains the pressure in the first heated chamber 134 based on one or more the desired throughput, process requirements, and the desired purity level between approximately. For example, the first pressure control valve 136 maintains the pressure in the first heated chamber between 1 mTorr and 100 Torr.

In another embodiment, the transport system 128 may include a third flow control component 138 and a second heated chamber 140. The second heated chamber 140 may be disposed between the second and third flow control components 132, 138. A pressure control valve 142, for example may be further associated with second heated chamber 210. First, second, and third flow control components 130, 132, 138 (also called flow controllers) are operative to control the flow of the high molecular mass borane from the interaction chamber 120 to the ion source chamber 102. Temperature of second heated chamber 140, for example, may be kept sufficient to rapidly condense the borane.

In another embodiment, the ion implantation system 100 may further comprise an accumulation chamber 144, wherein the accumulation chamber is disposed between second flow control component 132 and the ion source chamber 102. In the embodiment where system includes a third flow control component 138, accumulation chamber 144 is disposed between third flow control component and ion source chamber 102. The accumulation chamber 144, for example, is operative to collect high mass molecular borane which is not yet needed in the ion source chamber 102. While the present example illustrates multiple flow control components and heated chambers, any number of flow control components and chambers are contemplated as falling within the scope of the present disclosure.

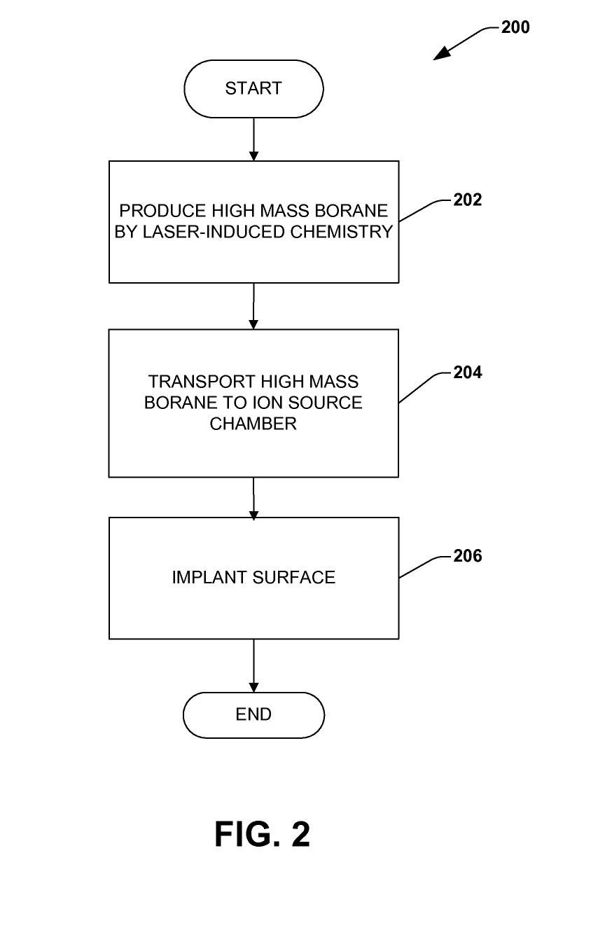

Referring now to FIG. 2, one exemplary embodiment of a methodology 200 of the disclosure is illustrated for laser-induced borane production for ion implantation. Although the methodology 200 is illustrated and described hereinafter as a series of acts or events, it will be appreciated that the disclosure is not limited by the illustrated ordering of such acts or events. For example, some acts may occur in different orders and/or concurrently with other acts or events apart from those illustrated and/or described herein, in accordance with one or more aspects of the disclosure. In addition, not all illustrated steps may be required to implement a methodology in accordance with the present disclosure. Furthermore, the methodologies according to the present disclosure may be implemented in association with the formation and/or processing of structures illustrated and described herein as well as in association with other structures not illustrated.

The method 200 begins at 202, wherein high mass borane molecules are produced by laser induced chemistry in an interaction chamber. For example, as illustrated in FIG. 1, a CO₂ laser light 125 having a wavelength of 10.6 μm, for example, is utilized to irradiate process gases, including diborane, from a gas source 116 which has been fed into interaction chamber 120. Using an R-16 (973 cm⁻¹) line of excitation, the v-14 wagging mode of B₂H₆ is excited, causing dissociation of the molecule.

At 204 of FIG. 2, a transport system transfers high mass borane produced in the interaction chamber to an ion source chamber for subsequent ion implantation in act 206. For example, act 204 transfers high mass borane to the ion source chamber in a series of steps through multiple flow control components and heated chambers. For example, while the laser 124 of FIG. 1 is inducing a chemical reaction in interaction chamber 120 to produce high mass borane, the first flow control component 130 may be open while the second flow control component 132 is closed. The third flow control component 138, for example, may remain open during ion implantation operations in act 206 of FIG. 2 in order to fuel the ion source chamber 102. The first heated chamber 134 of FIG. 1, for example, is heated to a temperature sufficient to condense high mass borane, while the interaction chamber 120 is heated to a temperature sufficient to keep high mass borane from condensing.

After a predetermined period of time, a high mass molecular borane is thus transferred to the ion source chamber 102. Thus, the first flow control component 130 will close and the first heated chamber 134 will be cooled to a temperature sufficient that a vapor pressure is low enough not to spike the pressure within the ion source chamber 102 beyond a predetermined limit. The second flow control component 134, for example, will then be opened while simultaneously reducing the temperature of the second heated chamber 140 to a level suitable to rapidly condense the desired high mass molecular borane. Concurrently, the temperature of the first heated chamber 134 will be increased to a temperature for rapidly evaporating the high mass molecular borane, resulting in a transfer of the high mass molecular borane from the first heated chamber, through the second flow control component 132 to the second heated chamber 140. In another example, the high mass molecular borane further flows through the third flow control component 138 and into the ion source chamber 102.

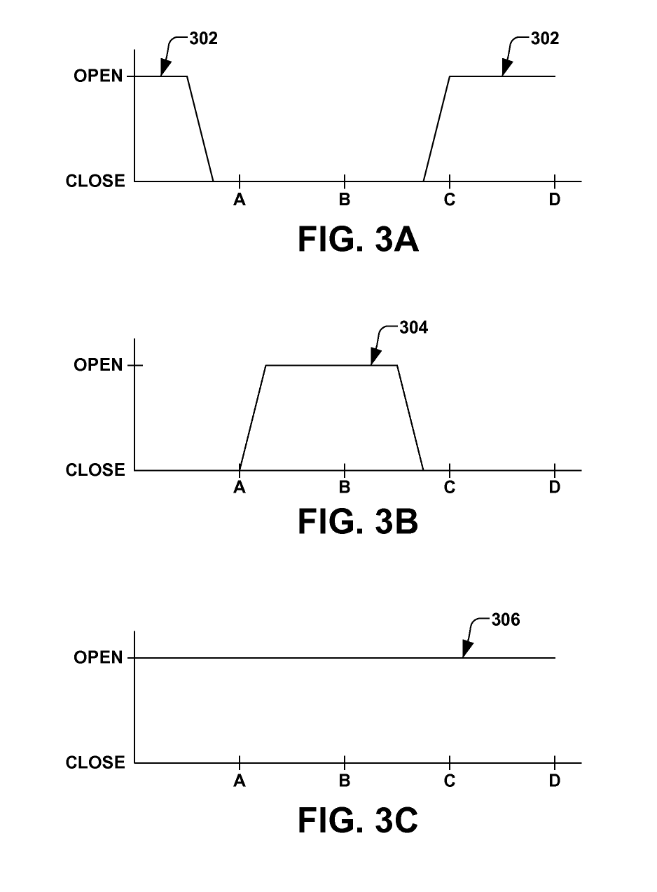

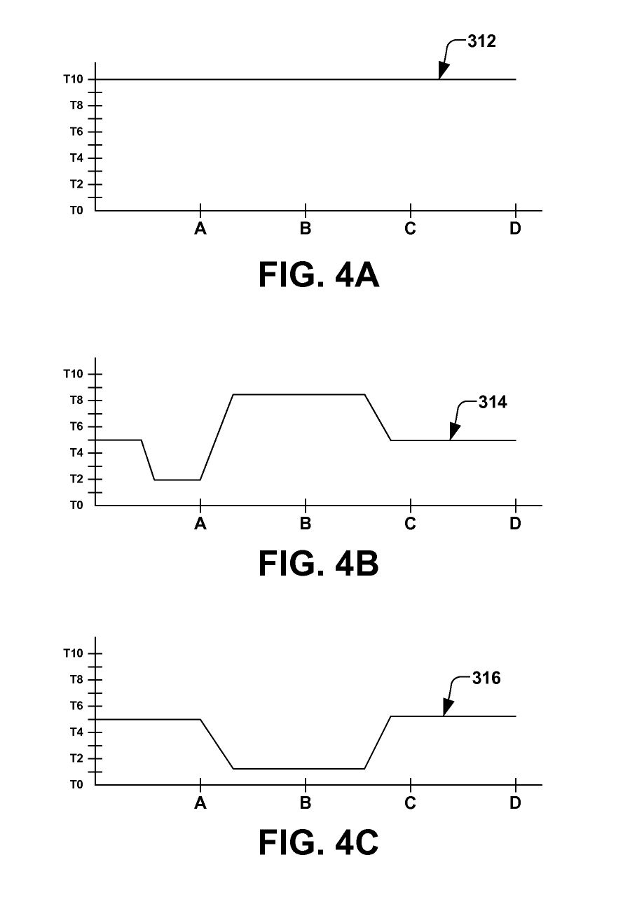

FIGS. 3A-3C, for example, respectively illustrate valve positions 302, 304, 306 (e.g., opened or closed) of the first flow control component 130, second flow control component 132, and third flow component 138 at successive times A, B, C, and D in accordance with one example. Accordingly, in conjunction with FIGS. 3A-3C, FIGS. 4A-4C illustrate the respective temperature 312, 314, 316 of the interaction chamber 120, first heated chamber 134, and second heated chamber 140 of FIG. 1. The valve positions 302, 304, 306 of FIGS. 3A-3C and temperature differentials 312, 314, 316 of FIGS. 4A-4C thus controls the evolution of high mass borane through successive iterations of control of pressure and temperature, thus transporting the high mass borane from the interaction chamber 120 at high pressure to the ion source chamber 102 at lower pressure. Control of the first flow control component 130, second flow control component 132, and third flow component 138 of FIG. 1, along control of the temperature of the interaction chamber 120, first heated chamber 134, second heated chamber 140, and accumulation chamber 144 or ion source chamber 102 at the appropriate time thus advantageously provides the high mass borane to the ion source chamber not seen in the prior art.

In view of the foregoing structural and functional features described supra, methodologies in accordance with various aspects of the disclosure will be better appreciated with reference to the above figures and descriptions. While, for purposes of simplicity of explanation, the methodologies described below are depicted and described as executing serially, it is to be understood and appreciated that the present disclosure is not limited by the illustrated order, as some aspects could, in accordance with the present disclosure, occur in different orders and/or concurrently with other aspects from that depicted and described herein. Moreover, not all illustrated features may be required to implement a methodology in accordance with an aspect the present disclosure.

Although the disclosure has been illustrated and described above with respect to certain aspects and implementations, it will be appreciated that equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure, which performs the function in the herein illustrated exemplary implementations of the disclosure. In this regard, it will also be recognized that the disclosure may include a computer-readable medium having computer-executable instructions for performing the steps of the various methods of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “including”, “has”, “having”, “with” and variants thereof are used in either the detailed description or the claims, these terms are intended to be inclusive in a manner similar to the term “comprising”. Also, the term “exemplary” as utilized herein simply means example, rather than finest performer.

What is claimed is:

1. A method of for the production of high mass molecular boranes in an ion implantation comprising:
providing a laser;
irradiating diborane via the laser at a predetermined power level in a temperature and pressure controlled interaction chamber to produce the high mass molecular boranes;
transferring the high mass molecular boranes to an ion source chamber of the ion implantation system.

2. The method of claim 1, wherein the diborane is irradiated with a CO₂ laser at a wavelength of about 10.6 μm at a R-16 (973 cm⁻¹) line of excitation.

3. The method of claim 1, wherein the temperature of the interaction chamber comprises from about 40° C. to about 80° C. and the pressure of the interaction chamber comprises from about 50 torr to about 400 torr.

4. The method of claim 1, wherein the high mass molecular boranes comprise icosaborane or octadecaborane.

5. The method of claim 1, wherein transferring the high mass molecular borane to the ion source chamber comprises delivering the borane through a transfer system comprising at least a first and a second flow control component and at least a first heated chamber, wherein the first heated chamber is disposed between the first and second flow control components, and wherein the first heated chamber is operable to condense the high mass molecular borane.

6. The method of claim 5, wherein the transfer of the high mass molecular borane is a semi-continuous process.

7. The method of claim 5, the transferring of the high mass molecular borane further comprises delivering the high mass molecular borane through a third flow control component, wherein the third flow control component is operably coupled to the ion source chamber and a second heated chamber, wherein the second heated chamber disposed between the second and third flow control components.

8. The method of claim 1, further comprising accumulating high mass molecular borane in an accumulation chamber operably coupled to ion source chamber.

9. An interaction and transport system for the production and transfer of high mass molecular borane in an ion implantation system, the interaction and transport system comprising:
a temperature controlled interaction chamber;
at least a first and a second flow control component;
at least a first heated chamber, the first heated chamber disposed between the first and second flow control components, wherein the first heated chamber is operable to condense the high mass molecular borane.

10. The system of claim 9, wherein the interaction chamber comprises a heater configured to heat the interaction chamber to a temperature of from about 40° C. to about 80° C.

11. The system of claim 9, further comprising a third flow control component, wherein the third flow control component is coupled to an ion source chamber in the ion implantation system.

12. The system of claim 11, further comprising a second heated chamber, the second heated chamber disposed between the second and third flow control components.

13. The system of claim 9, wherein the first and second flow control components are configured to supply the high mass diborane to the ion source chamber in a semi-continuous manner.

14. The system of claim 11, wherein the first and second flow control components are configured to supply the high mass diborane to the ion source chamber such that the diborane produced in the interaction chamber is consumed at the same rate in the ion source chamber.

15. The system of claim 9, further comprising an accumulation chamber disposed between the second heated chamber and the ion source chamber.

16. A system for the production of high mass molecular diborane for ion implantation, the system comprising:
a laser;
a diborane source gas;
a heated interaction chamber for generating a high mass molecular borane;
a transport system for transferring the high mass molecular borane;
an ion source chamber for generating an ion beam in an ion beam path for implantation of a workpiece;
a beamline assembly that receives the ion beam from the ion source chamber and processes the ion beam; and
a process chamber that receives the ion beam from the beam line assembly and implants the ions into a workpiece.

17. The system of claim 16, wherein the laser comprises a CO₂ laser configured to irradiate the diborane source gas at a wavelength of about 10.6 μm at a R-16 (973 cm⁻¹) line of excitation.

18. The system of claim 17, wherein the high mass molecular borane comprises an octadecaborane or an icosaborane.

19. The system of claim 17, wherein the transport system comprises:
at least a first and a second flow control component;
at least a first heated chamber, wherein the first heated chamber is disposed between the first and second flow control components, and wherein the first heated chamber is configured to condense the high mass molecular borane.

20. The system of claim 17, further comprising an accumulation chamber disposed between the second heated chamber and the ion source chamber.
